(19) United States
(12) Patent Application Publication
(10) Pub. No.: US 2025/0227913 A1
(43) Pub. Date: Jul. 10, 2025

(54) SEMICONDUCTOR MEMORY DEVICE

(71) Applicant: SAMSUNG ELECTRONICS CO., LTD., SUWON-SI (KR)

(72) Inventors: Yoon Goo KANG, Suwon-si (KR); Dong Young KIM, Suwon-si (KR); Cheol Ho KIM, Suwon-si (KR); Jae Hong PARK, Suwon-si (KR); Seo Jin AHN, Suwon-si (KR); Seok Jae WON, Suwon-si (KR)

(21) Appl. No.: 18/929,752

(22) Filed: Oct. 29, 2024

(30) Foreign Application Priority Data
Jan. 5, 2024 (KR) 10-2024-0001915

(51) Int. Cl. H10B 12/00

(52) U.S. Cl. CPC H10B 12/315; H10B 12/482; H10B 12/485

(57) ABSTRACT

A semiconductor memory device includes a substrate that includes an active area defined by an element isolation film, a gate electrode within the substrate and that extends in a first direction, a buffer film on the substrate and that extends in a second direction that intersects the first direction, a direct contact that extends through the buffer film and contacts a portion of the active area, a conductive pattern on the direct contact and the buffer film and that extends in the second direction, and a capacitor structure on the substrate and that contacts another portion of the active area. The buffer film includes a lower buffer film and an upper buffer film on the lower buffer film, the upper buffer film includes a first upper insulating film, a third upper insulating film, and a second upper insulating film, and the third upper insulating film contains carbon (C).

### CROSS-REFERENCE TO RELATED APPLICATION

This application claims priority under 35 U.S.C. 119 from Korean Patent Application No. 10-2024-0001915, filed on Jan. 5, 2024 in the Korean Intellectual Property Office, the contents of which are herein incorporated by reference in their entirety.

### TECHNICAL FIELD

Embodiments of the present disclosure are directed to a semiconductor memory device.

### DISCUSSION OF THE RELATED ART

As semiconductor devices become more highly integrated, individual circuit patterns are becoming increasingly smaller to implement a larger number of semiconductor devices in the same area. For example, as an integration level of semiconductor devices increases, a design rule on components of the semiconductor device decreases.

In a highly scaled semiconductor device, a process of forming a plurality of gate electrodes, a plurality of contacts connected to the gate electrodes, and a plurality of conductive patterns has become increasingly complex and difficult.

### SUMMARY

Embodiments of the present disclosure provide a semiconductor memory device with increased reliability.

According to an embodiment of the present disclosure, there is provided a semiconductor memory device that includes a substrate that includes an active area defined by an element isolation film, a gate electrode disposed within the substrate and that extends in a first direction, a buffer film disposed on the substrate and that extends in a second direction that intersects the first direction, a direct contact that extends through the buffer film and contacts a portion of the active area, a conductive pattern disposed on the direct contact and the buffer film and that extends in the second direction, and a capacitor structure disposed on the substrate and that contacts another portion of the active area. The buffer film includes a lower buffer film and an upper buffer film disposed on the lower buffer film, the upper buffer film includes a first upper insulating film, a third upper insulating film, and a second upper insulating film that are sequentially stacked in a third direction intersecting the first and the second directions, and the third upper insulating film contains carbon (C).

According to another embodiment of the present disclosure, there is provided a semiconductor memory device that includes a substrate that includes an active area defined by an element isolation film, a gate electrode disposed within the substrate and that extends in a first direction, a lower buffer film disposed on the substrate and that extends in a second direction that intersects the first direction, an upper buffer film disposed on the lower buffer film and that extends in the second direction, a direct contact that extends through the lower buffer film and the upper buffer film and contacts a portion of the active area, a conductive pattern disposed on the direct contact and the upper buffer film and that extends in the second direction, and a capacitor structure disposed on the substrate and that contacts another portion of the active area. A width in the first direction of the lower buffer film is greater than a width in the first direction of the upper buffer film. The lower buffer film includes a first lower insulating film, a second lower insulating film disposed on the first lower insulating film, and a third lower insulating film disposed between the first lower insulating film and the second lower insulating film, the upper buffer film includes a first upper insulating film, a second upper insulating film disposed on the first upper insulating film, and a third upper insulating film disposed between the first upper insulating film and the second upper insulating film, and each of the third lower insulating film and the third upper insulating film includes a silicon carbonitride film (SiCN).

According to still another embodiment of the present disclosure, there is provided a semiconductor memory device that includes a substrate that includes an active area defined by an element isolation film, a gate electrode disposed within the substrate and that extends in a first direction, a lower buffer film disposed on the substrate and that extends in a second direction that intersects the first direction, an upper buffer film disposed on the lower buffer film and that extends in the second direction, a direct contact that extends through the lower buffer film and the upper buffer film and contacts a portion of the active area, a conductive pattern disposed on the direct contact and the upper buffer film and that extends in the second direction, a bit line spacer disposed along and on a sidewall of the conductive pattern and a sidewall of the upper buffer film, a buried contact disposed on the substrate and that contacts another portion of the active area, a landing pad electrically connected to the buried contact, and a capacitor structure electrically connected to the landing pad. The upper buffer film includes a first upper insulating film, a third upper insulating film, and a second upper insulating film that are sequentially stacked in a third direction that intersects the first and the second directions. The first upper insulating film includes a silicon oxide film, the second upper insulating film includes a silicon nitride film, the third upper insulating film includes a silicon carbonitride film (SiCN). The third upper insulating film has a thickness of 1 nm or less, a width in the first direction of the lower buffer film is greater than a width in the first direction of the upper buffer film, and at least a portion of the lower buffer film overlaps the bit line spacer in the third direction.

Specific details of other embodiments are included in the detailed description and drawings.

### BRIEF DESCRIPTION OF THE DRAWINGS

FIG. 1 is a top view of a semiconductor memory device according to some embodiments of the present disclosure.

FIG. 2 is an enlarged view of a P area in FIG. 1.

FIG. 3 is a cross-sectional view cut along a line A-A in FIG. 2.

FIG. 4 is a cross-sectional view cut along a line B-B in FIG. 2.

FIG. 5 is a cross-sectional view cut along a line C-C in FIG. 2.

FIG. 6 is an enlarged view of a Q area in FIG. 3.

FIGS. 7 to 12 illustrate semiconductor memory devices according to some embodiments of the present disclosure.

FIGS. 13 to 19 illustrate intermediate structures that correspond to intermediate steps of a method for manufacturing a semiconductor memory device according to some embodiments of the present disclosure.

### DETAILED DESCRIPTION

It will be understood that when a first component is described as being in contact with a second component, the first component is in direct contact with the second component, with no additional components interposed therebetween.

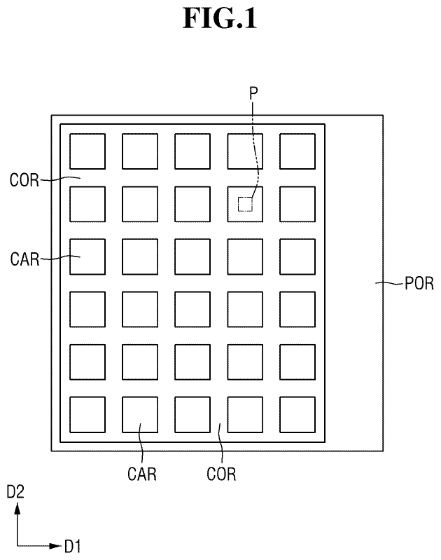

In the drawings of a semiconductor memory device according to some embodiments, a DRAM (Dynamic Random Access Memory) is shown by way of example. However, embodiments of the present disclosure are not necessarily limited thereto. Hereinafter, a semiconductor memory device according to some embodiments of the present disclosure will be described with referring to FIGS. 1 to 6.

FIG. 1 is a top view of a semiconductor memory device according to some embodiments of the present disclosure.

Referring to FIG. 1, the semiconductor memory device according to some embodiments includes cell areas CAR. The cell areas CAR include a plurality of memory cells. Each of a plurality of cell areas CAR constitutes one unit cell block. The cell areas CAR are spaced apart from each other in a first direction D1 and a second direction D2, and a core area COR is disposed between the cell areas CAR. The core area COR is where a sense amplifier and a write driver are provided. A peripheral circuit area POR is provided on one side of the cell areas CAR. The peripheral circuit area POR includes a row decoder, a column decoder, etc. Although the peripheral circuit area POR is shown as being disposed on one side of the cell areas CAR, the peripheral circuit area POR may be also disposed on other sides of the cell areas CAR.

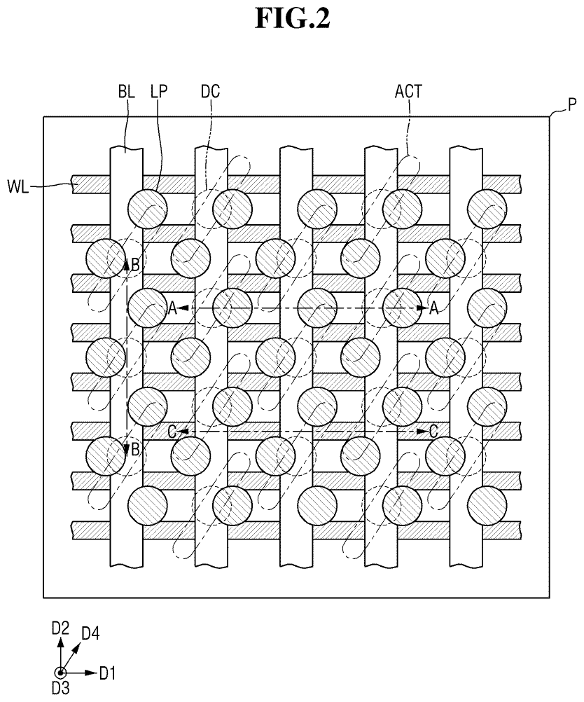

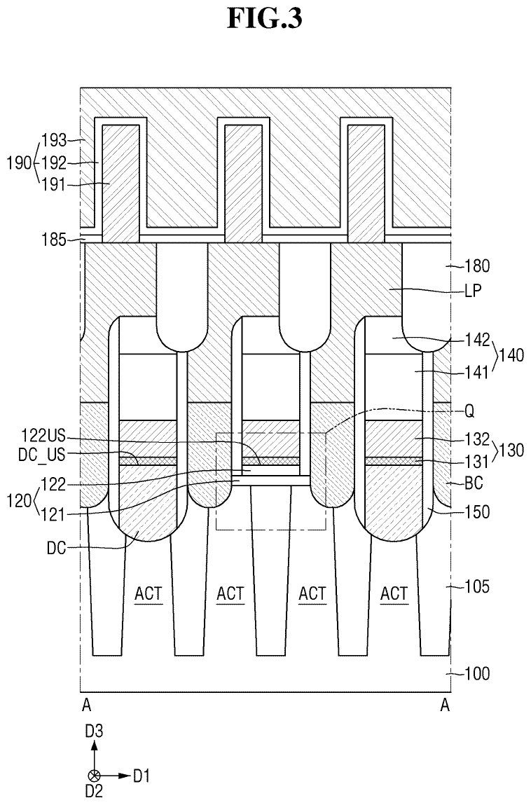

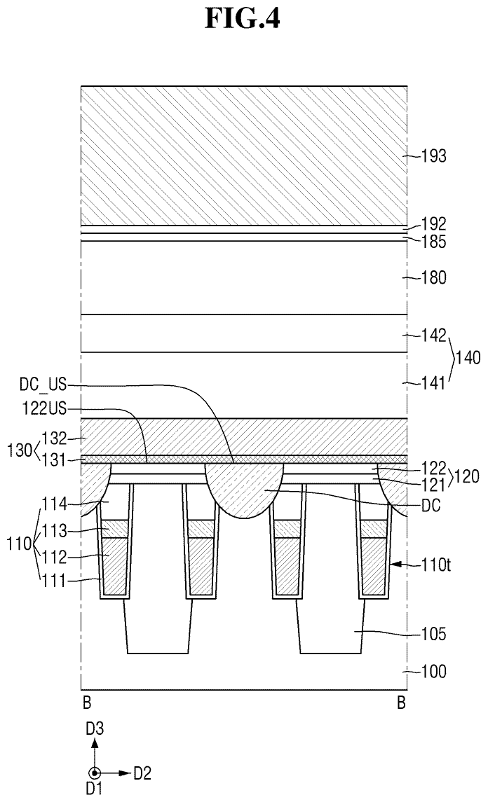

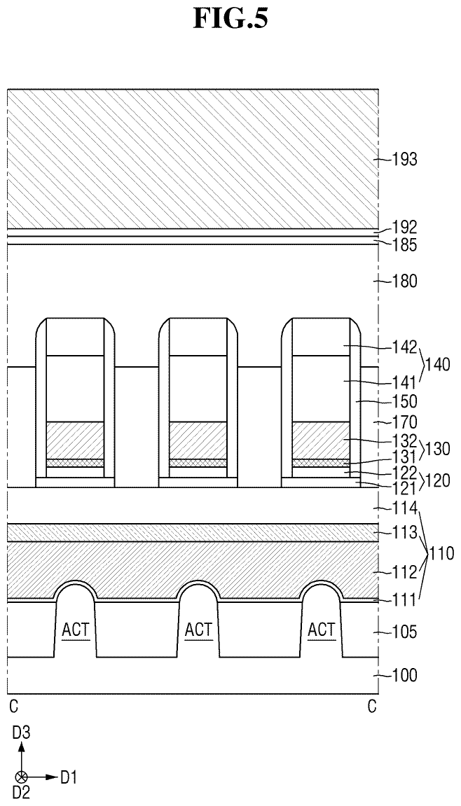

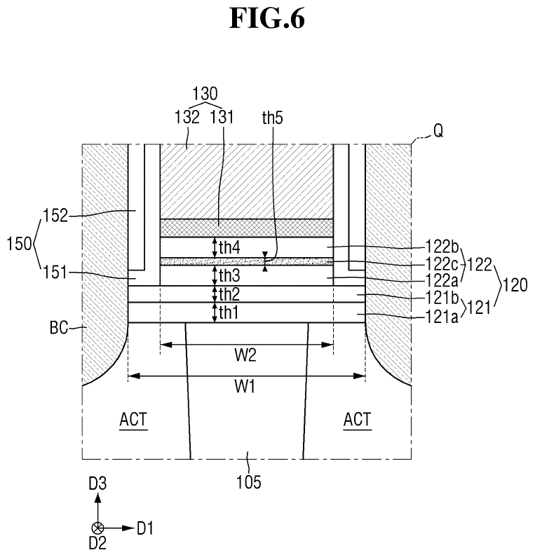

FIG. 2 is an enlarged view of a P area in FIG. 1. FIG. 3 is a cross-sectional view along a line A-A in FIG. 2. FIG. 4 is a cross-sectional view along a line B-B in FIG. 2. FIG. 5 is a cross-sectional view cut along a line C-C in FIG. 2. FIG. 6 is an enlarged view of a Q area in FIG. 3.

Referring to FIGS. 2 to 6, in some embodiments, a substrate 100 is provided. The substrate 100 may be, for example, a silicon single crystal substrate or a silicon on insulator (SOI) substrate. The substrate 100 may also include, but is not necessarily limited to, silicon germanium, SGOI (silicon germanium on insulator), indium antimonide, lead telluride compound, indium arsenide, indium phosphide, gallium arsenide, or gallium antimonide.

An element isolation film 105 is disposed within the substrate 100. An element isolation trench is formed within the substrate 100. The element isolation film 105 is disposed within the element isolation trench.

In addition, the element isolation film 105 includes a first liner film that conformally covers an inner wall and a bottom surface of the element isolation trench, a buried insulating film that fills the element isolation trench, and a second liner film interposed between the first liner film and the buried insulating film.

The first liner film is a silicon oxide film. The second liner film is a silicon nitride film. The buried insulating film is a silicon oxide film.

The element isolation film 105 defines a plurality of active areas ACT. As the design rule of the semiconductor memory device decreases, the plurality of active areas ACT form a bar that extends in a diagonal line or an oblique line, as shown in FIG. 2. For example, the plurality of active areas ACT extend in a fourth direction D4.

The plurality of active areas ACT are parallel to each other in the first direction D1. An end of one of the plurality of active areas ACT is adjacent to a center of another active area ACT adjacent thereto. In the present disclosure, the first direction D1, the second direction D2, the third direction D3, and the fourth direction D4 intersect each other. The first direction D1, the second direction D2, and the third direction D3 are substantially perpendicular to each other. The fourth direction D4, the first direction D1 and the second direction D2 constitute the same plane. That is, the fourth direction D4 is any direction between the first direction D1 and the second direction D2.

A semiconductor memory device according to some embodiments includes various contact arrangements formed on the plurality of active areas ACT. The various contact arrangements include, for example, a direct contact DC, a buried contact BC, and a landing pad LP.

For example, the direct contact DC electrically connects the plurality of active areas ACT to a bit line BL. The buried contact BC connects the plurality of active areas ACT to a capacitor lower electrode 191. Due to the arrangement structure, a contact area between the buried contact BC and the active area ACT is small. Accordingly, a conductive landing pad LP is introduced to increase a contact area thereof with the active area ACT and, at the same time, a contact area thereof with the capacitor lower electrode 191.

The landing pad LP is disposed between the active area ACT and the buried contact BC, and between the buried contact BC and the capacitor lower electrode 191. In a semiconductor memory device according to some embodiments, the landing pad LP is disposed between the buried contact BC and the capacitor lower electrode 191. The contact area is increased by the introduction of the landing pad LP, such that a contact resistance between the active area ACT and the capacitor lower electrode 191 is reduced.

Word lines WL are buried within the substrate 100. The word lines WL extend across the plurality of active areas ACT. The word lines WL extend in the first direction D1. The word lines WL are spaced apart from each other in the second direction D2. The word lines WL are buried in the substrate 100. In addition, a doped area is formed in the active areas ACT and between the word lines WL. The doped area is doped with N-type impurities.

A semiconductor memory device according to some embodiments includes a plurality of word line structures 110. Each of the plurality of word line structures 110 may be embedded in the substrate 100 and extend in the first direction D1. The plurality of word line structures 110 are spaced apart from each other in the second direction D2.

Each of the plurality of word line structures 110 includes a gate insulating film 111, a gate electrode 112, and a gate capping fill 113 and 114. The gate electrode 112 of the word line structure 110 corresponds to a word line WL of a semiconductor memory device according to some embodiments. Each of the plurality of word line structures 110 is disposed in a gate trench 110t formed in the substrate 100.

The gate insulating film 111 extends along an inner wall and a bottom surface of the gate trench 110t. The gate insulating film 111 extends along a profile of at least a portion of the gate trench 110t. The gate insulating film 111 includes at least one of silicon oxide, silicon nitride, silicon oxynitride, or a high dielectric constant material that has a higher dielectric constant than silicon oxide. The high dielectric constant material includes, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. However, embodiments of the present disclosure are not necessarily limited thereto.

The gate electrode 112 is disposed on the gate insulating film 111. The gate electrode 112 fills a portion of the gate trench 110t. The gate capping film 113 and 114 are disposed on the gate electrode 112. The gate capping film 113 and 114 fills a portion of the gate trench 110t that remains after the gate electrode 112 is formed therein.

In some embodiments, the gate capping film 113 and 114 include a gate capping conductive film 113 and a gate capping insulating film 114. The gate capping conductive film 113 and the gate capping insulating film 114 are sequentially stacked. For example, the gate capping insulating film 114 is disposed on the gate capping conductive film 113. The gate capping conductive film 113 includes, for example, polysilicon or polysilicon-germanium. However, embodiments of the present disclosure are not necessarily limited thereto. The gate capping insulating film 114 includes, for example, at least one of silicon nitride (SiN), silicon oxynitride (SiON), silicon oxide (SiO₂), silicon carbonitride (SiCN), silicon oxycarbonitride (SiOCN), or combinations thereof.

The gate electrode 112 includes at least one of a metal, a metal alloy, a conductive metal nitride, a conductive metal carbonitride, a conductive metal carbide, a metal silicide, a doped semiconductor material, a conductive metal oxynitride, or a conductive metal oxide. The gate electrode 112 includes, for example, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, or combinations thereof. However, embodiments of the present disclosure are not necessarily limited thereto.

A buffer film 120 is disposed on the substrate 100. The buffer film 120 extends in the second direction D2. The buffer film 120 includes a lower buffer film 121 and an upper buffer film 122 that are sequentially stacked in the third direction D3. For example, the upper buffer film 122 is disposed on the lower buffer film 121. The lower buffer film 121 is interposed between the substrate 100 and the upper buffer film 122. The buffer film 120 will be described in detail below with reference to FIG. 6.

Bit lines BL are disposed on the substrate 100. The bit lines BL are disposed on the buffer film 120. The bit lines BL intersect the word lines WL. The bit lines BL extend in the second direction D2. The bit lines BL are spaced apart from each other in the first direction D1. The bit line BL corresponds to a conductive pattern 130.

The conductive pattern 130 includes a first electrode 131 and a second electrode 132 that are sequentially stacked in the third direction D3. For example, the second electrode 132 is disposed on the first electrode 131. The first electrode 131 is in contact with the direct contact DC. In addition, the first electrode 131 is in contact with the buffer film 120. For example, the conductive pattern 130 contacts the buffer film 120. For example, the conductive pattern 130 contact the upper buffer film 122. For example, the first electrode 131 of the conductive pattern 130 contacts an upper surface 122US of the upper buffer film 122.

The first electrode 131 includes TiSiN. The second electrode 132 includes tungsten (W). However, embodiments of the present disclosure are not necessarily limited to thereto.

A bit line capping pattern 140 is disposed on the conductive pattern 130. The bit line capping pattern 140 includes a first capping pattern 141 and a second capping pattern 142 that are sequentially stacked. For example, the second capping pattern 142 is disposed on the first capping pattern 141. Each of the first capping pattern 141 and the second capping pattern 142 is a silicon nitride film.

A bit line spacer 150 is disposed on a sidewall of the conductive pattern 130 and a sidewall of the bit line capping pattern 140. In FIG. 3, the bit line spacer 150 is disposed on the substrate 100 and the element isolation film 105 in an area of the conductive pattern 130 where the direct contact DC is formed. However, in an area thereof where the direct contact DC is not formed, the bit line spacer 150 is disposed on the buffer film 120. For example, in the area thereof where the direct contact DC is not formed, the bit line spacer 150 is disposed on the lower buffer film 121.

The bit line spacer 150 contacts an upper surface of the lower buffer film 121. The bit line spacer 150 overlaps at least a portion of the lower buffer film 121 in the third direction D3. In addition, at least a portion of the bit line spacer 150 contacts a sidewall of the upper buffer film 122. At least a portion of the bit line spacer 150 overlaps the upper buffer film 122 in the first direction D1.

The bit line spacer 150 may include a single layer, or multiple layers. When the bit line spacer 150 has a single layer, the bit line spacer 150 is at least one of a silicon oxide film, a silicon nitride film, a silicon oxynitride film (SiON), or a silicon oxycarbonitride film (SiOCN). As shown in FIG. 6, when the bit line spacer 150 is formed in multiple layers, the bit line spacer 150 includes a first spacer 151 and a second spacer 152. The second spacer 152 is disposed on the first spacer 151. Each of the first spacer 151 and the second spacer 152 includes, for example, at least one of a silicon oxide film, a silicon nitride film, a silicon oxynitride film (SiON), a silicon oxycarbonitride film (SiOCN), air, or combinations thereof. However, embodiments of the present disclosure are not necessarily limited thereto.

The bit line BL is electrically connected to the doped area of the active area ACT by the direct contact DC. The direct contact DC is made of, for example, polysilicon doped with impurities.

The direct contact DC extends through the buffer film 120 and is connected to the active area ACT. The direct contact DC extends through both the upper buffer film 122 and the lower buffer film 121. An upper surface DC_US of the direct contact DC is coplanar with the upper surface 122US of the upper buffer film 122.

The buried contact BC is disposed between a pair of adjacent bit lines BL. The buried contacts BC are spaced apart from each other. The buried contact BC includes at least one of polysilicon doped with impurities, a conductive silicide compound, a conductive metal nitride, or a metal. The buried contacts BC have island shapes that are spaced apart from each other in a plan view. The buried contact BC extends through the buffer film 120 and comes into contact with the doped areas of the active area ACT. For example, the buried contact BC extends through the lower buffer film 121 of the buffer film 120 and comes into contact with the doped areas of the active area ACT.

The landing pad LP is formed on the buried contact BC. The landing pad LP is electrically connected to the buried contact BC. The landing pad LP overlaps a portion of an upper surface of the bit line BL. For example, the landing pad LP includes at least one of an impurity-doped semiconductor material, a conductive silicide compound, a conductive metal nitride, a conductive metal carbide, a metal, or a metal alloy.

A fence pattern 170 is disposed on the substrate 100 and the element isolation film 105. The fence pattern 170 is disposed on the word line structure 110. In addition, the fence pattern 170 overlaps the word line structure 110 formed within the substrate 100. The fence pattern 170 is disposed between the conductive patterns 130 that extend in the second direction D2. For example, the fence pattern 170 includes at least one of silicon oxide, silicon nitride, silicon oxynitride, or combinations thereof.

A pad isolation insulating film 180 is formed adjacent to the landing pad LP and on the conductive pattern 130. For example, the pad isolation insulating film 180 is disposed on the bit line capping pattern 140. The pad isolation insulating film 180 defines an area of the landing pad LP that constitutes the plurality of isolation areas. In addition, the pad isolation insulating film 180 does not cover an upper surface of the landing pad LP.

The pad isolation insulating film 180 includes an insulating material and electrically isolates the plurality of landing pads LP from each other. For example, the pad isolation insulating film 180 includes at least one of a silicon oxide film, a silicon nitride film, a silicon oxynitride film, a silicon oxycarbonitride film, or a silicon carbonitride film.

An etch stop film 185 is disposed on the pad isolation insulating film 180 and the landing pad LP. The etch stop film 185 includes at least one of a silicon nitride film, a silicon carbonitride film, a silicon boronitride film (SiBN), a silicon oxynitride film, or a silicon oxycarbide film.

A capacitor structure 190 is disposed on the landing pad LP. The capacitor structure 190 is electrically connected to the landing pad LP. A portion of the capacitor structure 190 is disposed within the etch stop film 185. The capacitor structure 190 includes a capacitor lower electrode 191, a capacitor dielectric film 192, and a capacitor upper electrode 193.

The capacitor lower electrode 191 is disposed on the landing pad LP. The capacitor lower electrode 191 is shown as having a pillar shape. However, embodiments of the present disclosure are not necessarily limited thereto. In some embodiments, the capacitor lower electrode 191 has a cylindrical shape. The capacitor dielectric film 192 is formed on the capacitor lower electrode 191. The capacitor dielectric film 192 is formed along a profile of the capacitor lower electrode 191. The capacitor upper electrode 193 is formed on the capacitor dielectric film 192. The capacitor upper electrode 193 surrounds an outer wall of the capacitor lower electrode 191.

In an embodiment, the capacitor dielectric film 192 vertically overlaps the capacitor upper electrode 193. In an embodiment, unlike what is shown, the capacitor dielectric film 192 includes a portion that vertically overlaps the capacitor upper electrode 193 and a portion that does not vertically overlap the capacitor upper electrode 193. For example, the portion of the capacitor dielectric film 192 that does not vertically overlap the capacitor upper electrode 193 is a portion not covered with the capacitor upper electrode 193.

Each of the capacitor lower electrode 191 and the capacitor upper electrode 193 includes, for example, a doped semiconductor material, a conductive metal nitride such as titanium nitride, tantalum nitride, niobium nitride or tungsten nitride, etc., a metal such as ruthenium, iridium, titanium, or tantalum, etc., or a conductive metal oxide such as iridium oxide or niobium oxide, etc. However, embodiments of the present disclosure are not necessarily limited thereto.

The capacitor dielectric film 192 includes, for example, one of silicon oxide, silicon nitride, silicon oxynitride, or a high-k material, or combinations thereof. However, embodiments of the present disclosure are not necessarily limited thereto. In a semiconductor memory device according to some embodiments, the capacitor dielectric film 192 includes a stacked film structure in which a zirconium oxide film, an aluminum oxide film, and a zirconium oxide film are sequentially stacked. In a semiconductor memory device according to some embodiments, the capacitor dielectric film 192 includes a dielectric film that includes hafnium (Hf). In a semiconductor memory device according to some embodiments, the capacitor dielectric film 192 has a stacked structure of a ferroelectric material film and a paraelectric material film.

Hereinafter, with reference to FIG. 6, the buffer film 120 according to some embodiments of the present disclosure is described in more detail.

Referring to FIG. 6, in some embodiments, the buffer film 120 includes a lower buffer film 121 and an upper buffer film 122. The lower buffer film 121 and the upper buffer film 122 are sequentially stacked in the third direction D3. For example, the upper buffer film 122 is disposed on the lower buffer film 121.

In some embodiments, a first width W1 in the first direction D1 of the lower buffer film 121 is greater than a second width W2 in the first direction D1 of the upper buffer film 122. This is because when the conductive pattern 130 is formed, the upper buffer film 122 is patterned like the conductive pattern 130, while the lower buffer film 121 is not patterned like the conductive pattern 130 when the conductive pattern 130 is formed. Therefore, the first width W1 is greater than the second width W2.

For example, the first width W1 is the smallest width in the first direction D1 of the lower buffer film 121. The second width W2 is the largest width in the first direction D1 of the upper buffer film 122. However, embodiments of the present disclosure are not necessarily limited thereto.

The lower buffer film 121 includes a first lower insulating film 121a and a second lower insulating film 121b. The first lower insulating film 121a and the second lower insulating film 121b are sequentially stacked in the third direction D3. For example, the second lower insulating film 121b is disposed on the first lower insulating film 121a.

The first lower insulating film 121a is disposed on the substrate 100 and the element isolation film 105. A portion of a lower surface of the first lower insulating film 121a is in contact with the substrate 100, and another portion of the lower surface of the first lower insulating film 121a contacts the element isolation film 105. A side wall of the first lower insulating film 121a is in contact with the buried contact BC. In FIG. 5, the side wall of the first lower insulating film 121a contacts the fence pattern 170.

The second lower insulating film 121b is interposed between the first lower insulating film 121a and the upper buffer film 122. The lower surface of the second lower insulating film 121b is in contact with the first lower insulating film 121a. An upper surface of the second lower insulating film 121b is in contact with the upper buffer film 122. For example, the upper surface of the second lower insulating film 121b contacts a first upper insulating film 122a. A side wall of the second lower insulating film 121b is in contact with the buried contact BC. In FIG. 5, the side wall of the second lower insulating film 121b is in contact with the fence pattern 170.

In some embodiments, each of the first lower insulating film 121a and the second lower insulating film 121b includes an insulating material. In an embodiment, the first lower insulating film 121a is a silicon oxide film. The second lower insulating film 121b is a silicon nitride film. However, embodiments of the present disclosure are not necessarily limited to thereto.

In some embodiments, the first lower insulating film 121a has a first thickness th1 in the third direction D3. The second lower insulating film 121b has a second thickness th2 in the third direction D3. The first thickness th1 is larger than the second thickness th2. In an embodiment, the first thickness th1 is about 3 nm, and the second thickness th2 is about 2 nm. However, embodiments of the present disclosure are not necessarily limited to thereto.

The upper buffer film 122 includes the first upper insulating film 122a, a second upper insulating film 122b, and a third upper insulating film 122c. The first upper insulating film 122a, the third upper insulating film 122c, and the second upper insulating film 122b are sequentially stacked in the third direction D3. For example, the second upper insulating film 122b is disposed on the first upper insulating film 122a. The third upper insulating film 122c is interposed between the first upper insulating film 122a and the second upper insulating film 122b. For example, the first upper insulating film 122a is disposed at the lowest level of the upper buffer film 122. The second upper insulating film 122b is disposed at the highest level of the upper buffer film 122. The third upper insulating film 122c is disposed at a middle level of the upper buffer film 122.

The first upper insulating film 122a is disposed on the lower buffer film 121. A lower surface of the first upper insulating film 122a contacts the lower buffer film 121. A sidewall of the first upper insulating film 122a contacts the bit line spacer 150. For example, the sidewall of the first upper insulating film 122a contacts the first spacer 151.

The second upper insulating film 122b is disposed on the first upper insulating film 122a. The second upper insulating film 122b is interposed between the first upper insulating film 121a and the conductive pattern 130. The lower surface of the second upper insulating film 122b is in contact with the third upper insulating film 122c. An upper surface of the second upper insulating film 122b is in contact with the conductive pattern 130. For example, the upper surface of the second upper insulating film 122b is in contact with the first electrode 131. A side wall of the second upper insulating film 122b is in contact with the first spacer 151.

The third upper insulating film 122c is disposed on the first upper insulating film 122a. The lower surface of the third upper insulating film 122c is in contact with the first upper insulating film 122a. The upper surface of the third upper insulating film 122c is in contact with the second upper insulating film 122b.

In some embodiments, each of the first upper insulating film 122a, the second upper insulating film 122b, and the third upper insulating film 122c includes an insulating material. In an embodiment, the first upper insulating film 122a is a silicon oxide film. The second upper insulating film 122b is a silicon nitride film. The third upper insulating film 122c is a silicon carbonitride film (SiCN). For example, the third upper insulating film 122c contains carbon (C). However, embodiments of the present disclosure are not necessarily limited to thereto.

In some embodiments, the first upper insulating film 122a has a third thickness th3 in the third direction D3. The second upper insulating film 122b has a fourth thickness th4 in the third direction D3. The third upper insulating film 122c has a fifth thickness th5 in the third direction D3. The third thickness th3 is equal to the fourth thickness th4. The fifth thickness th5 is smaller than each of the third thickness th3 and fourth thickness th4.

In an embodiment, each of the third thickness th3 and the fourth thickness th4 is about 3 nm. The fifth thickness th5 is 1 nm or less. However, embodiments of the present disclosure are not necessarily limited to thereto.

In some embodiments, since the upper buffer film 122 includes the third upper insulating film 122c, the buffer film 120 can be prevented from collapsing when a process that forms the direct contact DC and a subsequent process are performed. In addition, because the thickness of the third upper insulating film 122c is less than 1 nm, an etchant is effectively prevented from penetrating thereto in a subsequent process.

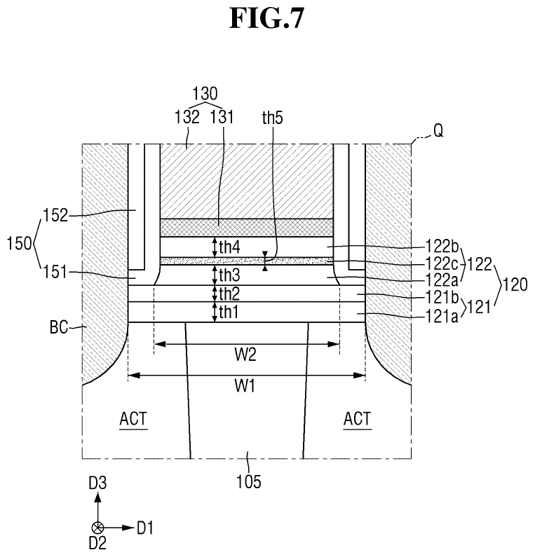

Hereinafter, a semiconductor memory device according to some further embodiments of the present disclosure is described with referring to FIGS. 7 to 12. For convenience of description, repeated descriptions of components described using FIG. 2 to FIG. 6 may be summarized or omitted.

FIGS. 7 to 12 illustrate a semiconductor memory device according to some embodiments of the present disclosure. For reference, FIGS. 7 to 12 are enlarged views of area Q of FIG. 3.

Referring to FIG. 7, in an embodiment, a sidewall of the upper buffer film 122 is inclined. For example, a sidewall of the first upper insulating film 122a of the upper buffer film 122 is inclined. For example, a width of the first upper insulating film 122a in the first direction D1 gradually decreases with increasing distance from the lower buffer film 121.

For example, each of a width of the second upper insulating film 122b and a width of the third upper insulating film 122c is constant with increasing distance from the lower buffer film 121. However, embodiments of the present disclosure are not necessarily limited thereto. In some embodiments, the width of each of the third upper insulating film 122c and the second upper insulating film 122b decreases with increasing distance from the lower buffer film 121. This may be because the first upper insulating film 122a is etched less in a process that patterns the conductive pattern 130.

The second width W2 of the upper buffer film 122 in the first direction D1 is a width of a lower surface of the first upper insulating film 122a in the first direction D1. The width of the lower surface of the first upper insulating film 122a in the first direction D1 is the largest width of the upper buffer film 122 in the first direction D1. The width of the lower surface of the first upper insulating film 122a in the first direction D1 is smaller than the first width W1 of the lower buffer film 121 in the first direction D1.

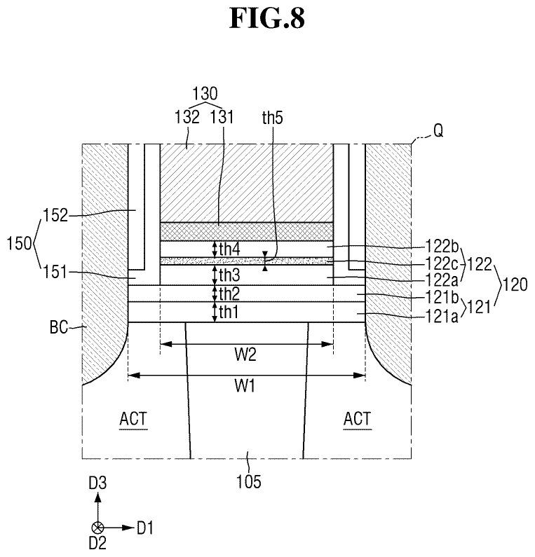

Referring to FIG. 8, in an embodiment, the third thickness th3 of the first upper insulating film 122a is greater than the fourth thickness th4 of the second upper insulating film 122b. The fourth thickness th4 of the second upper insulating film 122b is equal to the second thickness th2 of the second lower insulating film 121b. The third thickness th3 of the first upper insulating film 122a is equal to the first thickness th1 of the first lower insulating film 121a.

For example, each of the third thickness th3 of the first upper insulating film 122a and the first thickness th1 of the first lower insulating film 121a is about 3 nm. Each of the fourth thickness th4 of the second upper insulating film 122b and the second thickness th2 of the second lower insulating film 121b is about 2 nm. However, embodiments of the present disclosure are not necessarily limited thereto.

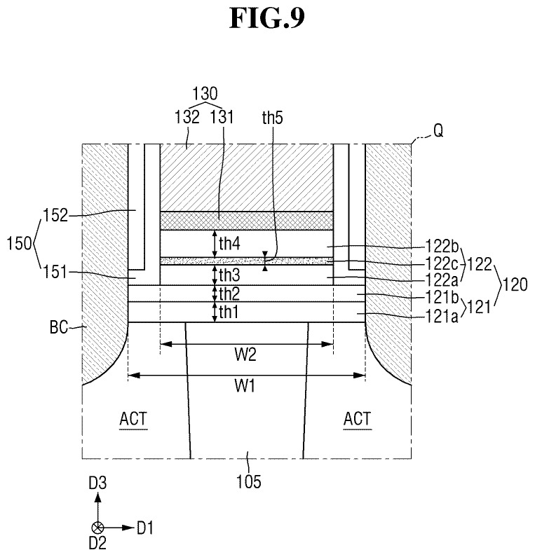

Referring to FIG. 9, in an embodiment, the third thickness th3 of the first upper insulating film 122a is smaller than the fourth thickness th4 of the second upper insulating film 122b. The fourth thickness th4 of the second upper insulating film 122b is greater than the second thickness th2 of the second lower insulating film 121b. The third thickness th3 of the first upper insulating film 122a is equal to the first thickness th1 of the first lower insulating film 121a.

For example, each of the third thickness th3 of the first upper insulating film 122a and the first thickness th1 of the first lower insulating film 121a is about 3 nm. The fourth thickness th4 of the second upper insulating film 122b is about 4 nm. The second thickness th2 of the second lower insulating film 121b is about 2 nm. However, embodiments of the present disclosure are not necessarily limited thereto.

For example, referring to FIG. 6, FIG. 8, and FIG. 9, the fourth thickness th4 of the second upper insulating film 122b is between 2 nm inclusive and 4 nm inclusive. However, embodiments of the present disclosure are not necessarily limited thereto.

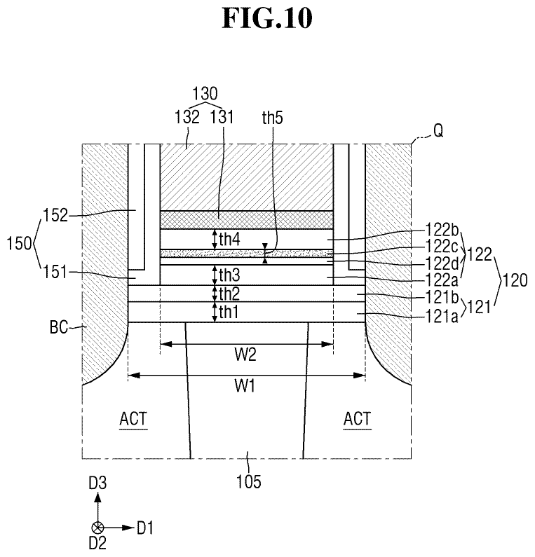

Referring to FIG. 10, in an embodiment, the upper buffer film 122 further includes a fourth upper insulating film 122d. For example, the upper buffer film 122 includes the first upper insulating film 121a, the second upper insulating film 122b, the third upper insulating film 122c, and the fourth upper insulating film 122d.

The first upper insulating film 122a, the fourth upper insulating film 122d, the third upper insulating film 122c, and the second upper insulating film 122b are sequentially stacked in the third direction D3. For example, the fourth upper insulating film 122d is disposed on the first upper insulating film 122a. The third upper insulating film 122c is disposed on the fourth upper insulating film 122d. The second upper insulating film 122b is disposed on the third upper insulating film 122c. For example, the fourth upper insulating film 122d is interposed between the first upper insulating film 122a and the third upper insulating film 122c. The third upper insulating film 122c is interposed between the fourth upper insulating film 122d and the second upper insulating film 122b.

In some embodiments, the fourth upper insulating film 122d includes silicon oxynitride film (SiON). Nitrogen (N) can react with silicon oxide in the first upper insulating film 122a before the third upper insulating film 122c is formed on the first upper insulating film 122a. The silicon oxide and nitrogen (N) react with each other to produce silicon oxynitride. However, embodiments of the present disclosure are not necessarily limited thereto.

In some embodiments, the fourth upper insulating film 122d is formed between the third upper insulating film 122c and the second upper insulating film 122b.

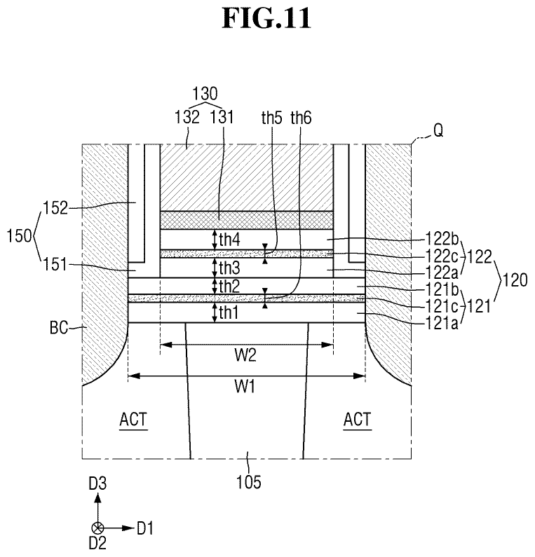

Referring to FIG. 11, in an embodiment, the lower buffer film 121 further includes a third lower insulating film 121c.

The first lower insulating film 121a, the third lower insulating film 121c, and the second lower insulating film 121b are sequentially stacked in the third direction D3. For example, the second lower insulating film 121b is disposed on the first lower insulating film 121a. The third lower insulating film 121c is interposed between the first lower insulating film 121a and the second lower insulating film 121b. For example, the first lower insulating film 121a is disposed at the lowest level of the lower buffer film 121. The second lower insulating film 121b is disposed at the highest level of the lower buffer film 121. The third lower insulating film 121c is disposed at the middle level of the lower buffer film 121.

The third lower insulating film 121c is disposed on the first lower insulating film 121a. A lower surface of the third lower insulating film 121c is in contact with the first lower insulating film 121a. An upper surface of the third lower insulating film 121c is in contact with the second lower insulating film 121b. The third lower insulating film 121c is a silicon carbonitride film (SiCN). For example, the third lower insulating film 121c contains carbon (C).

In some embodiments, the third lower insulating film 121c has a sixth thickness th6 in the third direction D3. The sixth thickness th6 of the third lower insulating film 121c is equal to the fifth thickness th5 of the third upper insulating film 122c. For example, the sixth thickness th6 of the third lower insulating film 121c is 1 nm or less.

In some embodiments, since the lower buffer film 121 includes the third lower insulating film 121c, the buffer film 120 can be prevented from collapsing when a process that forms the direct contact DC and a subsequent process are performed. Moreover, because the thickness of the third lower insulating film 121c is less than mm, an etchant is effectively prevented from penetrating thereto in the subsequent process.

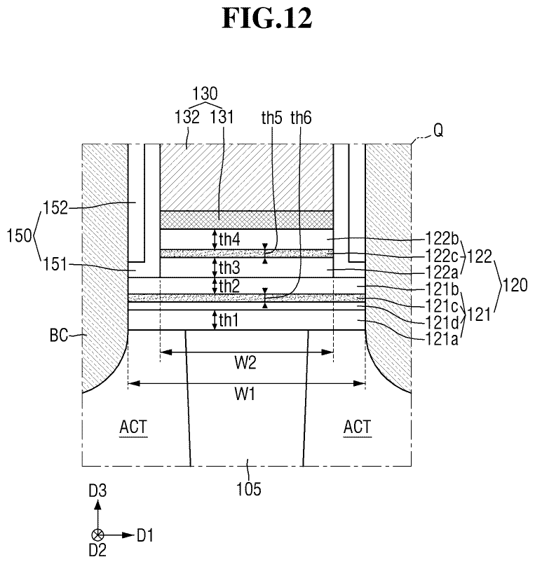

Referring to FIG. 12, in an embodiment, the lower buffer film 121 further includes a fourth upper insulating film 122d. For example, the lower buffer film 121 includes the first lower insulating film 121a, the second lower insulating film 121b, the third lower insulating film 121c, and the fourth lower insulating film 121d.

The first lower insulating film 121a, the fourth lower insulating film 121d, the third lower insulating film 121c, and the second lower insulating film 121b are sequentially stacked in the third direction D3. For example, the fourth lower insulating film 121d is disposed on the first lower insulating film 121a. The third lower insulating film 121c is disposed on the fourth lower insulating film 121d. The second lower insulating film 121b is disposed on the third lower insulating film 121c. For example, the fourth lower insulating film 121d is interposed between the first lower insulating film 121a and the third lower insulating film 121c. The third lower insulating film 121c is interposed between the fourth lower insulating film 121d and the second lower insulating film 121b.

In some embodiments, the fourth lower insulating film 121d is a silicon oxynitride film (SiON). Nitrogen (N) can react with silicon oxide in the first lower insulating film 121a before the third lower insulating film 121c is formed on the first lower insulating film 121a. The silicon oxide and nitrogen N react with each other to produce silicon oxynitride. However, embodiments of the present disclosure are not necessarily limited to thereto.

In some embodiments, the fourth lower insulating film 121d is formed between the third lower insulating film 121c and the second lower insulating film 121b.

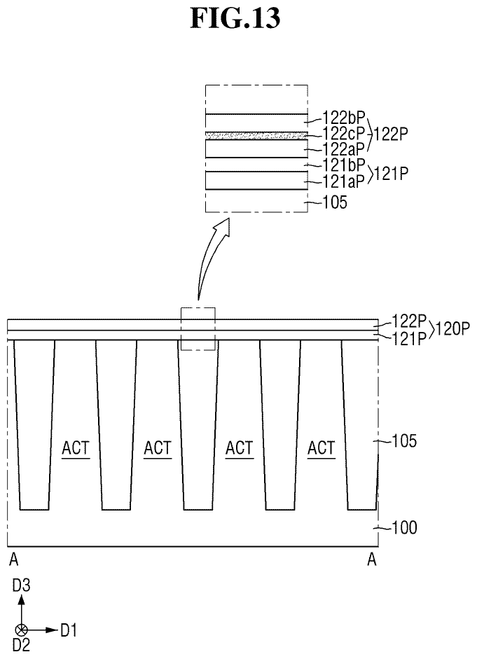

Hereinafter, with reference to FIGS. 13 to 19, a method for manufacturing a semiconductor memory device according to some embodiments of the present disclosure is described.

FIGS. 13 to 19 illustrate intermediate structures that correspond to intermediate steps of a method for manufacturing a semiconductor memory device according to some embodiments of the present disclosure.

Referring to FIG. 13, in an embodiment, the substrate 100 is provided. The element isolation film 105 is formed within the substrate 100. The element isolation film 105 defines the active areas ACT. The word line WL are formed within the substrate 100. The gate trench (110t in FIG. 4) is formed within the substrate 100. The gate trench extends in the first direction D1. The gate insulating film (111 in FIG. 4), the gate electrode (112 in FIG. 4), and the gate capping film (113 and 114 in FIG. 4) are formed within the gate trench.

An ion implantation process is performed on an entire surface of the substrate 100. The ion implantation process forms the doped area within the active area ACT.

A pre-buffer film 120P is formed on the substrate 100. The pre-buffer film 120P is formed along the upper surface of the substrate 100 and the upper surface of the element isolation film 105. The pre-buffer film 120P includes a pre-lower buffer film 121P and a pre-upper buffer film 122P. The pre-lower buffer film 121P is formed, and then the pre-upper buffer film 122P is formed.

The pre-lower buffer film 121P includes a pre-first lower insulating film 121aP and a pre-second lower insulating film 121bP. The pre-upper buffer film 122P includes a pre-first upper insulating film 122aP, a pre-third upper insulating film 122cP, and a pre-second upper insulating film 122bP.

The pre-first lower insulating film 121aP is formed. The pre-first lower insulating film 121aP is a silicon oxide film. The pre-second lower insulating film 121bP is formed. The pre-second lower insulating film 121bP is a silicon nitride film. the pre-first upper insulating film 122aP may be formed. The pre-first upper insulating film 122aP is embodied as a silicon oxide film. The pre-third upper insulating film 122cP is formed. The pre-third upper insulating film 122cP is a silicon carbonitride film (SiCN). The pre-second upper insulating film 122bP is formed. The pre-second upper insulating film 122bP is a silicon nitride film.

In some embodiments, the pre-first upper insulating film 122aP, the pre-third upper insulating film 122cP, and the pre-second upper insulating film 122bP are formed in-situ.

Forming the pre-third upper insulating film 122cP includes providing a hexachlorodisilane (HCD) precursor, providing ethene gas, applying heat, and providing ammonia gas.

For example, defining providing the hexachlorodisilane (HCD) precursor, providing the ethene gas, applying the heat, and providing the ammonia gas as one cycle, the pre-third upper insulating film 122cP is formed by repeating two or more cycles.

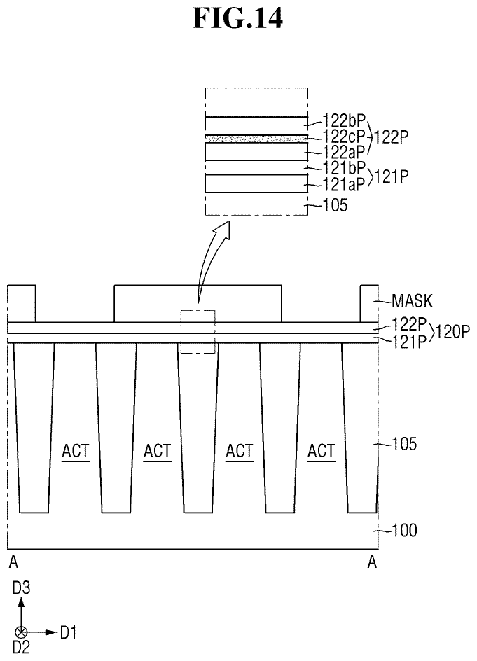

Referring to FIG. 14, in an embodiment, a mask film MASK is formed on the buffer film 120. The mask film MASK has an opening formed therein that roughly defines a position of the direct contact DC. The mask film MASK is at least one of a photoresist film, an amorphous carbon layer (ACL), a spin on hardmask (SOH), a spin on carbon (SOC) film, a silicon oxide film, or a silicon nitride film.

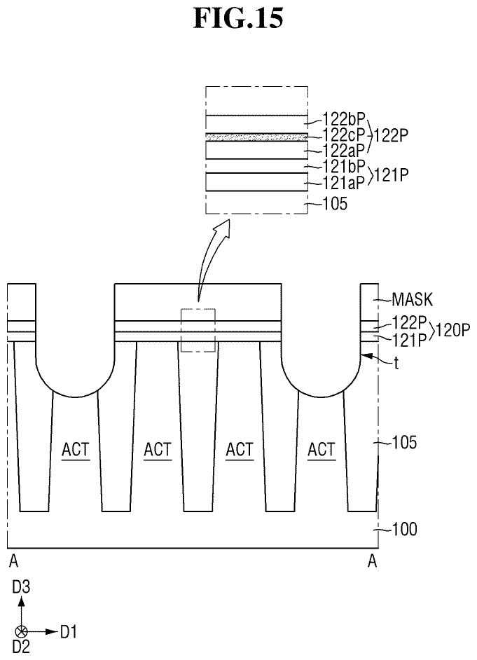

Referring to FIG. 15, in an embodiment, a trench t is formed using the mask film MASK as an etch mask. For example, the trench t extends through a portion of the pre-buffer film 120P. In addition, a portion of the element isolation film 105 and a portion of the substrate 100 are removed.

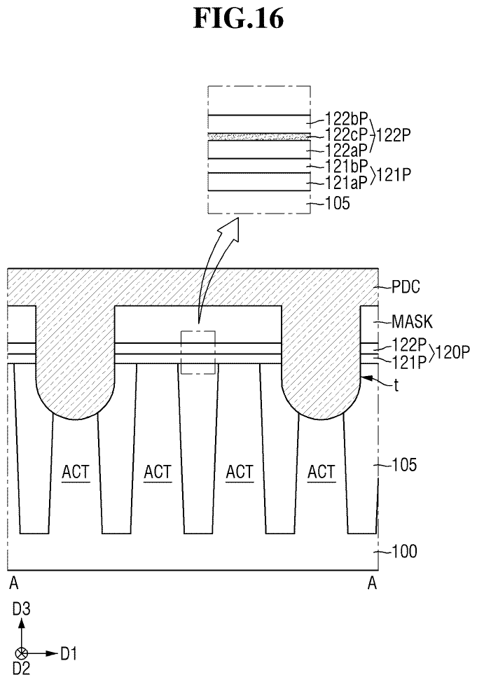

Referring to FIG. 16, in an embodiment, a pre-direct contact PDC is formed. The pre-direct contact PDC fills the trench t. The pre-direct contact PDC covers an entire upper surface of the mask film MASK. The pre-direct contact PDC is a polysilicon film doped with impurities.

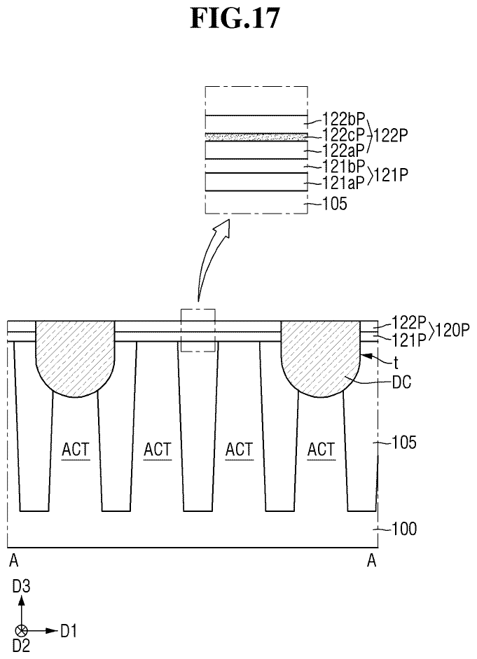

Referring to FIG. 17, in an embodiment, a CMP process is performed that partially removes the pre-direct contact PDC and forms the direct contact DC. The pre-buffer film 120P is exposed through the CMP process. Therefore, an upper surface of the pre-buffer film 120P is coplanar with the upper surface of the direct contact DC.

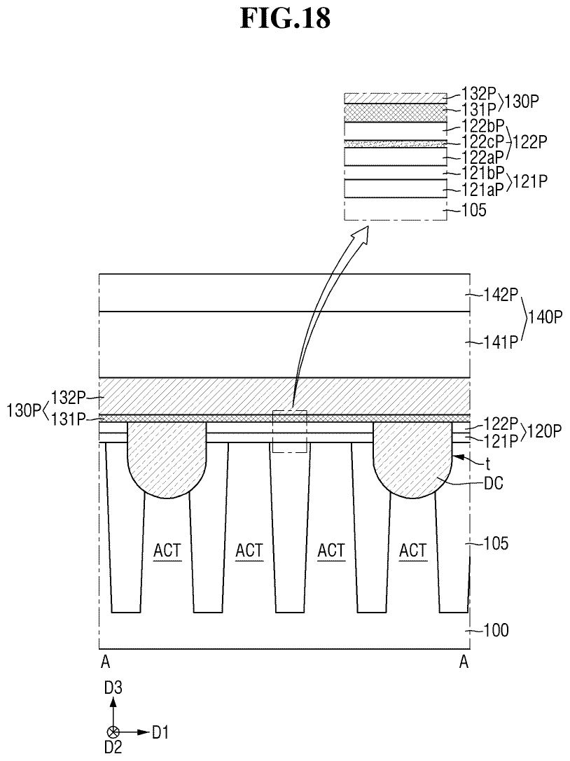

Referring to FIG. 18, in an embodiment, a pre-first electrode 131P, a pre-second electrode 132P, a pre-first capping pattern 141P, and a pre-second capping pattern 142P are sequentially formed. The pre-first electrode 131P, the pre-second electrode 132P, the pre-first capping pattern 141P, and the pre-second capping pattern 142P are formed on the pre-buffer film 120P and the direct contact DC. The pre-the first electrode 131P and the pre-second electrode 132P constitutive a pre-conductive pattern 130P. The pre-first capping pattern 141P and the pre-second capping pattern 142P constitute a pre-bit line capping pattern 140P.

The pre-first electrode 131P is a TiSiN film. The pre-second electrode 132P is a tungsten (W) film. Each of the pre-first capping pattern 141P and the pre-second capping pattern 142P is a silicon nitride film.

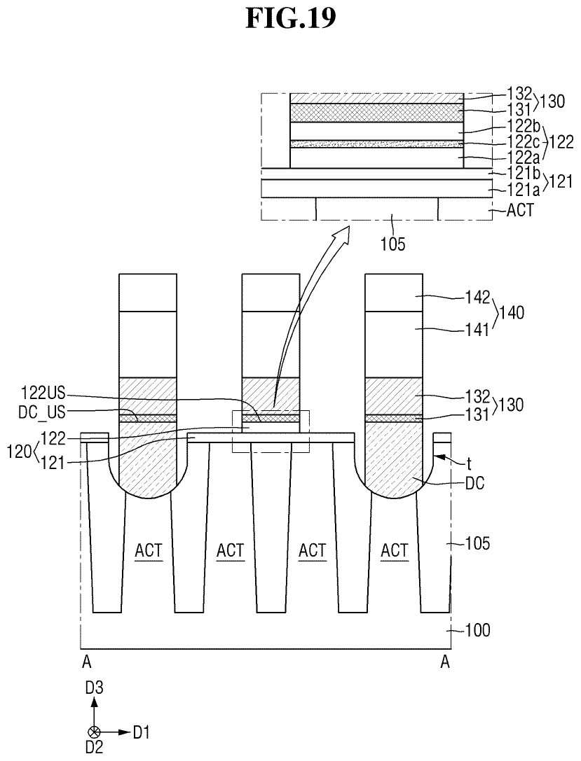

Referring to FIG. 19, in an embodiment, the pre-first electrode 131P, the pre-second electrode 132P, the pre-first capping pattern 141P, and the pre-second capping pattern 142P are patterned to form the conductive pattern 130 and the bit line capping pattern 140. For example, a portion of the pre-buffer film 120P is patterned. The pre-upper buffer film 122P and the pre-lower buffer film 121P are simultaneously patterned. The pre-upper buffer film 122P is patterned to form the upper buffer film 122. The pre-lower buffer film 121P is patterned to form the lower buffer film 121.

The lower buffer film 121 includes the first lower insulating film 121a and the second lower insulating film 121b. The upper buffer film 122 includes the first upper insulating film 122a, the second upper insulating film 122b, and the third upper insulating film 122c. Because the upper buffer film 122 includes the third upper insulating film 122c, the upper buffer film 122 can be prevented from collapsing in a subsequent process. Accordingly, a semiconductor memory device with increased reliability can be manufactured.

Although embodiments of the present disclosure have been described with reference to the accompanying drawings, the present disclosure is not limited to the above embodiments but can be implemented in various different forms. A person skilled in the art may appreciate that embodiments of the present disclosure can be practiced in other concrete forms without changing the technical spirit or essential characteristics of the present disclosure. Therefore, it should be appreciated that the embodiments as described above are not restrictive but illustrative in all respects.

What is claimed is:

1. A semiconductor memory device, comprising:
a substrate that includes an active area defined by an element isolation film;
a gate electrode disposed within the substrate and that extends in a first direction;
a buffer film disposed on the substrate and that extends in a second direction that intersects the first direction;
a direct contact that extends through the buffer film and contacts a portion of the active area;
a conductive pattern disposed on the direct contact and the buffer film and that extends in the second direction; and
a capacitor structure disposed on the substrate and that contacts another portion of the active area,
wherein the buffer film includes a lower buffer film and an upper buffer film disposed on the lower buffer film,
wherein the upper buffer film includes a first upper insulating film, a third upper insulating film, and a second upper insulating film that are sequentially stacked in a third direction that intersects the first and the second directions,
wherein the third upper insulating film contains carbon (C).

2. The semiconductor memory device of claim 1, wherein an upper surface of the upper buffer film is in contact with the conductive pattern.

3. The semiconductor memory device of claim 1, wherein an upper surface of the upper buffer film is coplanar with an upper surface of the direct contact.

4. The semiconductor memory device of claim 1,
wherein the first upper insulating film includes a silicon oxide film,
wherein the second upper insulating film includes a silicon nitride film.

5. The semiconductor memory device of claim 1, wherein a third upper insulating film has a thickness of 1 nm or less in the third direction.

6. The semiconductor memory device of claim 1, wherein a width in the first direction of the lower buffer film is greater than a width in the first direction of the upper buffer film.

7. The semiconductor memory device of claim 1, further comprising
a bit line spacer disposed along and on a sidewall of the conductive pattern,
wherein at least a portion of the lower buffer film overlaps the bit line spacer in the third direction.

8. The semiconductor memory device of claim 7, wherein at least a portion of the bit line spacer is in contact with a sidewall of the upper buffer film.

9. The semiconductor memory device of claim 1, wherein a width in the first direction of the first upper insulating film gradually decreases with increasing distance from the lower buffer film.

10. The semiconductor memory device of claim 1, wherein a thickness of the third upper insulating film in the third direction is smaller than a thickness of each of the first upper insulating film in the third direction and the second upper insulating film in the third direction.

11. A semiconductor memory device, comprising:
a substrate that includes an active area defined by an element isolation film;
a gate electrode disposed within the substrate and that extends in a first direction;
a lower buffer film disposed on the substrate and that extends in a second direction that intersects the first direction;
an upper buffer film disposed on the lower buffer film and that extends in the second direction;
a direct contact that extends through the lower buffer film and the upper buffer film and contacts a portion of the active area;
a conductive pattern disposed on the direct contact and the upper buffer film and that extends in the second direction; and
a capacitor structure disposed on the substrate and contacts another portion of the active area,
wherein a width in the first direction of the lower buffer film is greater than a width in the first direction of the upper buffer film,
wherein the lower buffer film includes a first lower insulating film, a second lower insulating film disposed on the first lower insulating film, and a third lower insulating film disposed between the first lower insulating film and the second lower insulating film,
wherein the upper buffer film includes a first upper insulating film, a second upper insulating film disposed on the first upper insulating film, and a third upper insulating film disposed between the first upper insulating film and the second upper insulating film,
wherein each of the third lower insulating film and the third upper insulating film includes a silicon carbonitride film (SiCN).

12. The semiconductor memory device of claim 11, wherein each of the third lower insulating film and the third upper insulating film has a thickness of 1 nm or less.

13. The semiconductor memory device of claim 11, wherein an upper surface of the upper buffer film is in contact with the conductive pattern.

14. The semiconductor memory device of claim 11, wherein an upper surface of the upper buffer film is coplanar with an upper surface of the direct contact.

15. The semiconductor memory device of claim 11,
wherein each of the first upper insulating film and the first lower insulating film includes a silicon oxide film,
wherein each of the second upper insulating film and the second lower insulating film includes a silicon nitride film.

16. The semiconductor memory device of claim 11, wherein a width in the first direction of the first upper insulating film gradually decreases with increasing distance from the lower buffer film.

17. The semiconductor memory device of claim 11, wherein a thickness of the third lower insulating film is smaller than a thickness of each of the first lower insulating film and the second lower insulating film.

18. The semiconductor memory device of claim 11, wherein a thickness of the first lower insulating film is equal to a thickness of the first upper insulating film.

19. The semiconductor memory device of claim 11, wherein a thickness of the second lower insulating film differs from a thickness of the second upper insulating film.

20. A semiconductor memory device, comprising:
a substrate that includes an active area defined by an element isolation film;
a gate electrode disposed within the substrate and that extends in a first direction;
a lower buffer film disposed on the substrate and that extends in a second direction that intersects the first direction;
an upper buffer film disposed on the lower buffer film and that extends in the second direction;
a direct contact that extends through the lower buffer film and the upper buffer film and contacts a portion of the active area;
a conductive pattern disposed on the direct contact and the upper buffer film and that extends in the second direction;
a bit line spacer disposed along and on a sidewall of the conductive pattern and a sidewall of the upper buffer film;
a buried contact disposed on the substrate and that contacts another portion of the active area;
a landing pad electrically connected to the buried contact; and
a capacitor structure electrically connected to the landing pad,
wherein the upper buffer film includes a first upper insulating film, a third upper insulating film, and a second upper insulating film that are sequentially stacked in a third direction that intersects the first and the second directions,
wherein the first upper insulating film includes a silicon oxide film,
wherein the second upper insulating film includes a silicon nitride film,
wherein the third upper insulating film includes a silicon carbonitride film (SiCN),
wherein the third upper insulating film has a thickness of 1 nm or less,
wherein a width in the first direction of the lower buffer film is greater than a width in the first direction of the upper buffer film,
wherein at least a portion of the lower buffer film overlaps the bit line spacer in the third direction.
